(19) United States
(12) Patent Application Publication
(10) Pub. No.: US 2012/0273259 A1
(43) Pub. Date: Nov. 1, 2012

(54) SIGNAL TRANSMISSION DEVICES AND PORTABLE RADIO COMMUNICATION DEVICES COMPRISING SUCH SIGNAL TRANSMISSION DEVICES

(76) Inventor: Ulf Palin, Ljustero (SE)

(21) Appl. No.: 13/543,919

(22) Filed: Jul. 9, 2012

Related U.S. Application Data
(63) Continuation of application No. PCT/EP2010/051277, filed on Feb. 3, 2010.

(51) Int. Cl. H05K 1/02

(52) U.S. Cl. 174/254

(57) ABSTRACT

In an exemplary embodiment, a signal transmission device generally includes a foldable conductive trace carrier having a first side and a second side. The carrier has a midsection between a first lateral section and a second lateral section. The midsection includes a first central primary conductive trace. First and second secondary conductive traces are respectively on each side of the primary conductive trace on the first side. The carrier is foldable for folding the first lateral section over the first side of the midsection and the second lateral section under the second side of the midsection. The first lateral section includes a first solid area of conductive material, and the second lateral section includes a second solid area of conductive material for forming a shielded conductor when the carrier is folded.

### CROSS-REFERENCE TO RELATED APPLICATION

This application is a continuation of PCT International Patent Application No. PCT/EP2010/051277 filed Feb. 3, 2010, published as WO2011/095206. The entire disclosure of the above application is incorporated herein by reference.

### FIELD

The present disclosure relates to signal transmission devices providing shielded conductors and portable radio communication devices having such an signal transmission device.

### BACKGROUND

This section provides background information related to the present disclosure which is not necessarily prior art.

Coaxial cables are made of a central conductor surrounded by an isolator/dielectric and a shield or circular conductor. These cables are used for interconnecting various entities such as antennas and radio circuits in order to receive and transmit radio signals. A coaxial cable may typically have an outer diameter of about 0.8 millimeters (mm).

The reception and transmission of radio signals is the core activity of portable radio communication devices, such as mobile phones. The dimensions of these devices have for many years become smaller and smaller. The height may be as low as 10 mm. For these types of devices, this means that also the size of the coaxial cable is a major concern. It is, therefore, desirable to reduce the size of coaxial cables.

One way to reduce the size is through providing the coaxial cable using a flexible carrier, such as flexfilm. The company Techno Core does for instance develop coaxial cables that are small. These coaxial cables are produced using a Liquid Crystal Polymer (LCP) film. On this film, there is provided a central main conductive trace in-between two secondary conductive traces. The whole film is then surrounded by a separate shield.

### SUMMARY

This section provides a general summary of the disclosure, and is not a comprehensive disclosure of its full scope or all of its features.

Exemplary embodiments are disclosed of foldable signal transmission devices and portable radio communication devices including the same. In an exemplary embodiment, a signal transmission device generally includes a foldable conductive trace carrier having a first side and a second side. The carrier has a midsection between a first lateral section and a second lateral section. The midsection includes a first central primary conductive trace. First and second secondary conductive traces are respectively on each side of the primary conductive trace on the first side. The carrier is foldable for folding the first lateral section over the first side of the midsection and the second lateral section under the second side of the midsection. The first lateral section includes a first solid area of conductive material, and the second lateral section includes a second solid area of conductive material for forming a shielded conductor when the carrier is folded.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a front view of a portable radio communication device;

FIG. 2 is a perspective view of a signal transmission device according to a first exemplary embodiment including a first and a second part of a foldable conductive trace carrier;

FIG. 3 is a side view of the first and second parts of the foldable conductive trace carrier shown in FIG. 2 as seen from a first end of the first part when in the process of being folded;

FIG. 4 is a perspective view from the first end of the first part of the foldable conductive trace carrier shown in FIGS. 2 and 3 as seen from the first end of the first part and also being in the process of being folded;

FIG. 5 is a side view from the first end of the first part of the foldable conductive trace carrier after being folded;

FIG. 6 is a perspective view from the first end of the first part of the foldable conductive trace carrier, with which a connecting part has been joined; and

FIG. 7 is a perspective view from the first end of the first part with connecting part and illustrating a connector attached to the connecting part; and

FIG. 8 is a perspective view from a first end of a first part of a foldable conductive trace carrier according to a variation where a single sided flexfilm is used for providing a signal transmission device.

### DETAILED DESCRIPTION

Example embodiments will now be described more fully with reference to the accompanying drawings.

Exemplary embodiments are disclosed of signal transmission devices that can be used as shielded conductors with relatively small dimensions. A foldable carrier carrying conductive material can be used for providing both conductor and shield of a shielded conductor.

According to various aspects, exemplary embodiments are disclosed of a conductive trace carrier having a first and a second side and a first part having a midsection, a first lateral section, and a second lateral section. The midsection is between the first and second lateral sections. The midsection includes a first central primary conductive trace on the first side of the carrier. First and second secondary conductive traces are on each side of the primary conductive trace on the first side of the carrier. The first part of the carrier is foldable for folding the first lateral section over the first side of the midsection and the second lateral section under the second, opposite side of the midsection in order to cover the midsection. The first lateral section includes a first solid area of conductive material, while the second lateral section is provided with a second solid area of conductive material in order to form a shielded conductor when the first part of the carrier is folded. Also disclosed are exemplary embodiments of electronic devices that include such a signal transmission device.

Disclosed exemplary embodiments of signal transmission devices have several advantages. It makes it possible to provide a very thin shielded signal conductor, which is of advantage when the signal transmission device is provided in very thin portable radio communication devices. Other advantages of the signal transmission device are that it is economical to produce because a small amount of inexpensive components may be used.

Accordingly, aspects of the present disclosure are directed towards providing a signal transmission device using a flexible carrier with conductive traces for forming a shielded connection that can be made even smaller. Aspects of the present disclosure are also generally directed towards a signal transmission device that is based on a foldable conductive trace carrier and a portable electronic device including such a signal transmission device, where the foldable conductive trace carrier is supposed to be folded for providing a shielded conductor for transmitting signals such as radio signals.

With reference to the figures, FIG. 1 shows a front view of a portable radio communication device 10, such as a mobile phone. The portable radio communication device 10 can be another type of device, such as a laptop computer, palm top computer, a TV receiver, or an FM radio receiver. The device 10 is, as an example, provided with a display 12 and a keypad 14 placed close to respective upper and lower ends of the device 10. These are here provided on the casing of the device 10. The device may also be provided without a display and/or without a keypad. The device 10 is also provided with at least one antenna. All antennas may be provided inside or in the interior of the device 10.

In order to provide an element such as an antenna with signals or to receive signals from such an element, the element needs to be connected to other elements and entities using conductors. As an antenna receives radio signals, a conductor used for it normally has to be shielded. Exemplary embodiments disclosed herein are directed towards providing a signal transmission device that provides such a shielded conductor for an element such as an antenna element. This conductor is provided through the use of a foldable conductive trace carrier, such as a flexfilm.

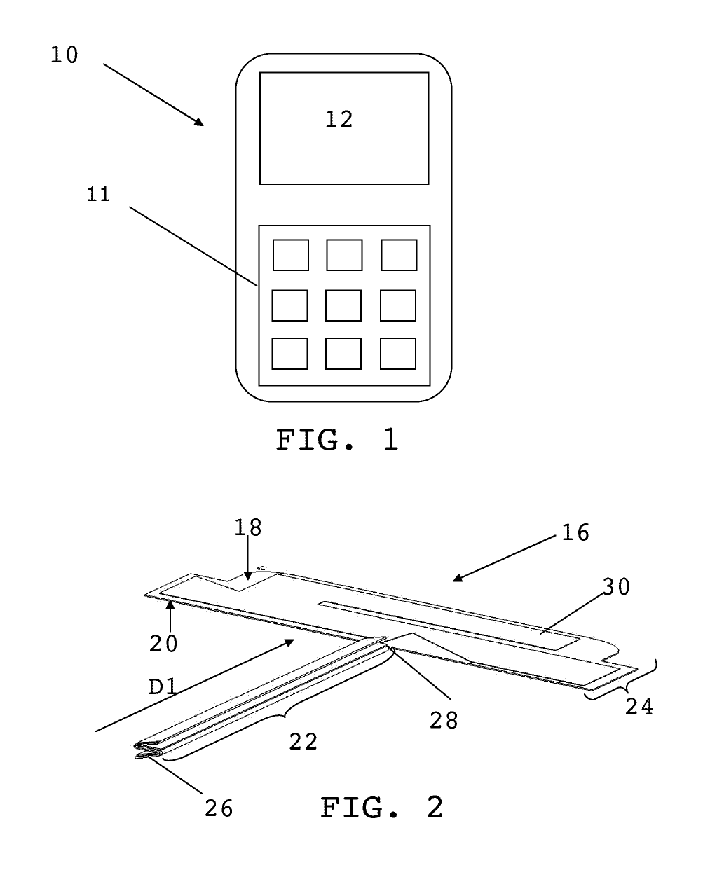

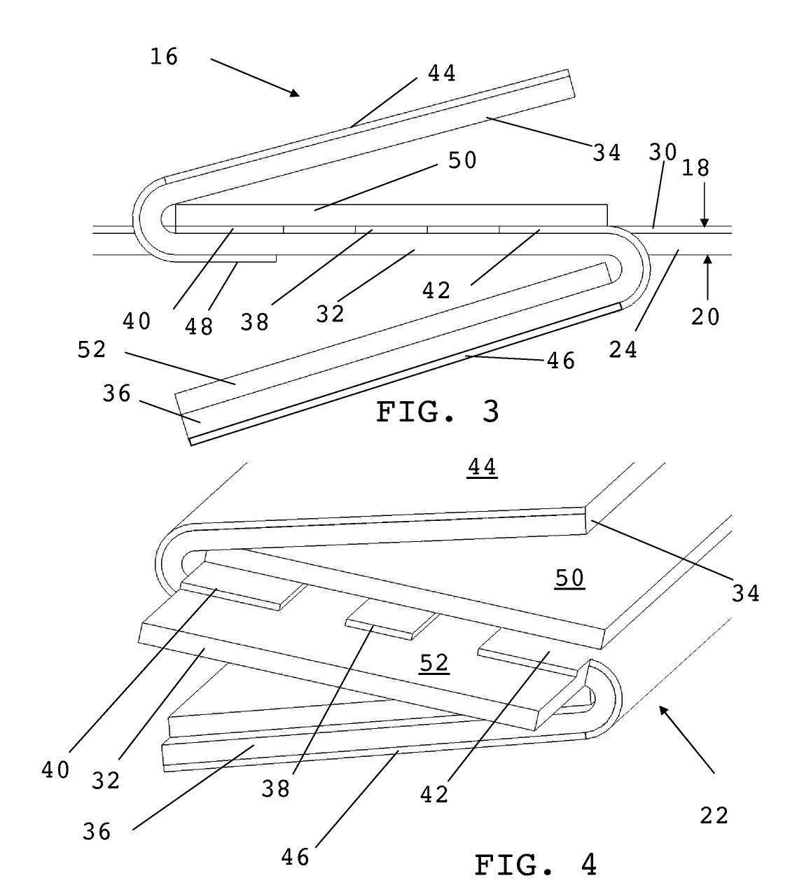

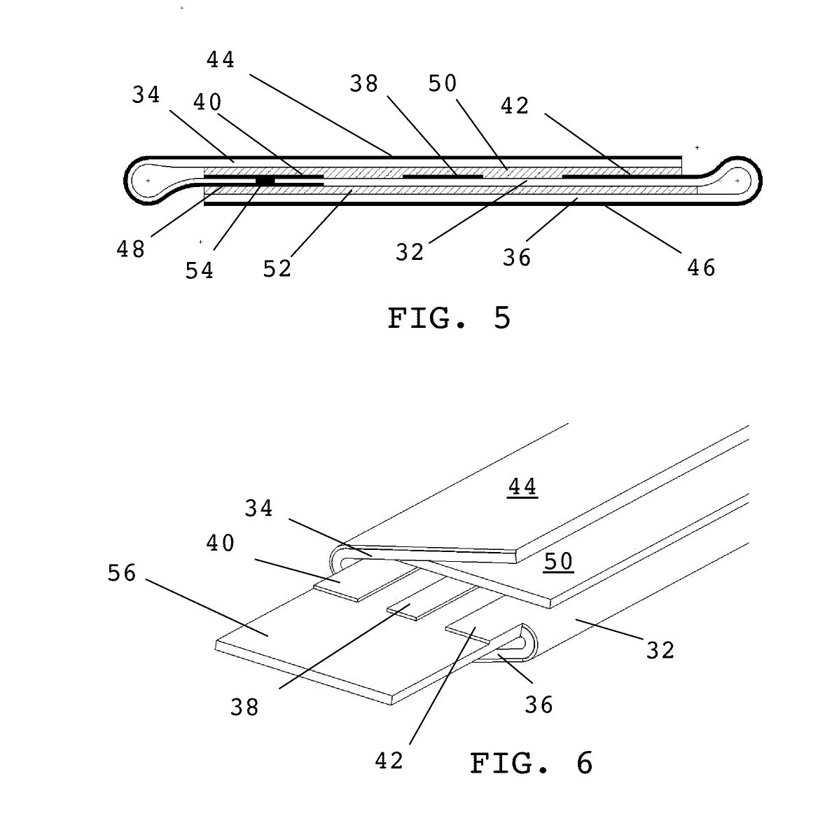

FIG. 2 shows a perspective view of a signal transmission device 16 embodying one or more aspects of the present disclosure. As shown in FIG. 2, the signal transmission device 16 comprises a foldable conductive trace carrier including a first 22 and a second 24 part. FIG. 3 shows a side view of the first and second parts 22 and 24 of the foldable conductive trace carrier as seen from a first end of the first part 22 when it is in the process of being folded. FIG. 4 shows a perspective view of the first end of the first part 22 of the foldable conductive trace carrier as it is being folded. FIG. 5 shows a side view from the first end of the first part 22 of the foldable conductive trace carrier after being folded.

As shown in FIG. 2, the foldable conductive trace carrier has two sides a first side 18, here also termed an upper side, and a second opposite side 20, here also termed bottom side. When the carrier is unfolded, these sides 18 and 20 are provided in two parallel planes. In FIGS. 2 and 3, the first part 22 is presented partially folded, while the second part 24 is straight or planar and non-folded. Thereby, it can be seen that the first and second sides 18 and 20 are parallel. The foldable conductive trace carrier is in the first embodiment provided through a flexfilm, which may be a polyethylene terephthalate (PET), polyethylene naphthalate (PEN) or a polyimide (PI) flexfilm. The foldable conductive trace carrier does in a first embodiment include at least two parts, a first part 22 and a second part 24, where the first part 22 is foldable, elongated and stretches from a first end 26 to a second end 28 along a first direction D1. The second part 24 is joined to the first part 22 at this second end 28 and is here also elongated but with the direction of elongation perpendicular to the direction of elongation of the first part. This second part may have any shape. As is more clearly seen in FIGS. 3 through 5, the first part 22 here includes a midsection 32 provided between a first and second lateral section 34 and 36. It is this midsection 32 that the second part 24 is joined to. These sections may all be essentially planar, but may get slightly curved at the areas where they are folded.

The first and second lateral sections 34 and 36 can here each be folded around a dedicated axis pointing in the first direction D1, where each such axis is provided at opposing sides or edges of the midsection. Both these sections can thus be folded at right angles to the first direction D1. The first part 22 of the carrier is thus foldable for placing the first lateral section 34 over the first side 18 of the midsection 32 as well as for placing the second lateral side 36 under the second, opposite side 20 of the midsection 32 in order to cover the midsection 32.

The second part 24 is here provided with an element, which is here an antenna element 30, which may be provided through placing a patterned area of electrically conducting material, such as copper, on the second part 24. It is here possible that also the second part 24 is foldable. It may for instance be foldable around an axis that is perpendicular to the axes around which the lateral sections of the first part 22 are foldable and therefore also perpendicular to the first direction D1. The second part 24 may thus be foldable in the first direction D1 or in a direction that is opposite to the first direction D1. It can be foldable in other directions. There is no requirement that this second part 24 is foldable. The second part 24 of the carrier need not be provided in some embodiments and may be omitted. The second end of the first part 22 of the carrier may for instance be connected to a separate element not provided on the carrier, for instance via a connector placed at the second end of the first part 22.

The midsection 32 of the first part 22 is provided with or includes a number of conductive traces 38, 40, 42 on the first side 18. These conductive traces may also with advantage be provided through copper that has been placed on the carrier. Of these traces, there is a first central primary conductive trace 38. This trace 38 stretches in the first direction D1 on the first side 18 of the carrier from the first end 26 of the first part 22 to the second end 28 of the first part 22. On both sides of this primary conductive trace 38, there are provided secondary conductive traces 40 and 42. These traces 40 and 42 are spaced an equal distance from the primary conductive trace 38 and run in parallel with it from the first end 26 to the second end 28 of the first part 22 on the first side 18 of the carrier. There is here a first secondary trace 40 provided adjacent the first lateral section 34 and a second secondary trace 42 adjacent the second lateral section 36.

The first lateral section 34 also includes conductive material. But this material is provided on the second side 20 of the carrier. This material here includes a first solid area 44 of conductive material, with advantage copper. This first solid area 44 here furthermore stretches along the first direction D1 for the whole length of the first part of the carrier all the way from the first end 26 to the second end 28. The first solid area 44 also stretches at right angles to the first direction from a first position covering the first secondary conductive trace 40 to a second position at least partly covering the second secondary conductive trace 42 when the first part 22 of the carrier is folded.

Also, the second lateral section 36 includes conductive material, for instance copper. But this material is provided on the first carrier side 18. On this side, there is a second solid area 46 of conductive material. The second solid area 46 is here joined with the second secondary conductive trace 42 of the midsection 32 along the first direction D1 for the whole length of the first part 22 of the carrier. They are thus formed as a unitary unit. The second solid area 46 then stretches from a first position where it is joined to the second secondary conductive trace 42 at right angles to the first direction to a second position where the second solid area 46 at least partly covers the first secondary conductive trace 40 when the first part 22 of the carrier is folded.

These solid areas 44 and 46 are provided together with the secondary conductive traces 40 and 42 in order to provide shielding for the primary conductive trace 38, in order to provide a shielded conductor. In order to do this, the first secondary conductive trace 40 is electrically connected to the conductive material of the first lateral section, and then more particularly to the first solid area 44 of the first lateral section. This may be done through providing a group of vias including at least one via 54 going through the carrier. Here, vias filled with conductive material like copper run through the midsection 32 from the first side 18 to the second side 20.

In order to provide this connection, the midsection 32 may furthermore be provided with a third solid area 48 of conductive material, like copper, on the second carrier side, where this third solid area 48 then stretches from the first end 26 to the second end 28. This third solid area 48 is furthermore with advantage aligned with the first secondary conductive trace 40 in order for the vias to directly connect the first secondary conductive trace 40 with the third solid area 48. The vias may then be provided regularly, for instance, at equally spaced distances along the first direction from the first end 26 to the second end 28. In this first embodiment, the third solid area 48 is furthermore joined with the first solid area 44. They may thus be provided as a unitary unit.

As the lateral sections 34 and 36 are then folded around the midsection 32, a shielded primary conductor 38 is provided, which may be provided as a coaxial cable. The folded sections can in one embodiment be separated by a dielectric, which may be air. In the first embodiment, the folded sections are separated by a first layer 50 and a second layer 52 of adhesive material. This helps in sealing the device and keeping it closed for shielding the primary conductive trace. The adhesive material has furthermore with advantage also dielectric properties, in which case insulation of the primary conductive trace 38 from the secondary conductive traces 40 and 42 and the solid areas 44, 46 and 48 is obtained. The first layer 50 of adhesive material is then inserted between the first lateral section 34 and the midsection 32. The second layer 52 of adhesive material is inserted between the second lateral section 46 and the midsection 32. The adhesive material may with advantage be an acrylic adhesive or some other type of low loss adhesive.

Because the conductive material is provided on different sides of the carrier material, the distance between the first solid area and the primary conductive trace and the distance between the second solid area and the primary conductive trace may differ from each other. In order to make these distances equal for improving the voltage distribution in the signal transmission device, it is then possible to make the second layer 52 of adhesive material thicker than the first layer 50 of adhesive material.

The coaxial cable provided through the folded first part of the flexible carrier is in the first embodiment connected to the element on the second part of the carrier. This connection is provided at the second end of the first part. When this element is an antenna element, this element may be connected to only the central primary conductive trace. In addition to this connection, the element may also be connected to the shielding. Whether an antenna element is connected to the shielding or not is dependent on the type of antenna.

In this way, it is possible to provide a very thin shielded signal conductor, which is of advantage when the signal transmission device is provided in very thin portable radio communication devices. The total thickness of the signal transmission device can be in an interval of 0.3 mm to 0.35 mm and with advantage 0.32 mm, which is a considerable size reduction as compared with a conventional coaxial cable. Other advantages of the signal transmission device are that it is economical to produce because a small amount of inexpensive components may be used. The use of a double sided flexible carrier also enables a more flexible design. The signal transmission device can furthermore be designed to provide a defined interface impedance at the first end, for instance, an impedance of 50 ohms (Ω).

In order to get connected to elements other than the antenna element 30, it is possible to provide the signal transmission device with a connector. FIGS. 6 and 7 are directed towards such a case. FIG. 6 shows a perspective view of the first end of the first part of the foldable conductive trace carrier to which a connecting part has been joined. FIG. 7 shows a perspective view of the first part with the connecting part, when a connector has been attached to this connecting part.

As can be seen in FIGS. 6 and 7, the carrier further includes a connecting part 56 which is joined to the first end 26 of the first part of the carrier. This connecting part 56 then stretches out in an opposite direction of the first direction. Here, the primary conductive trace 38 and the secondary conductive traces 40 and 42 all stretch out from the first end onto the connecting part 56. But he lateral sections 34 and 36 and the solid areas of conducting material do not, as they end at the first side 26. In this way, it is possible to place and mount a connector 58 (FIG. 7) on this connecting part 56. The connector 58 may be a surface mount connector soldered to the primary conductive trace 38 and optionally also to one or both of the secondary traces 40 and 42.

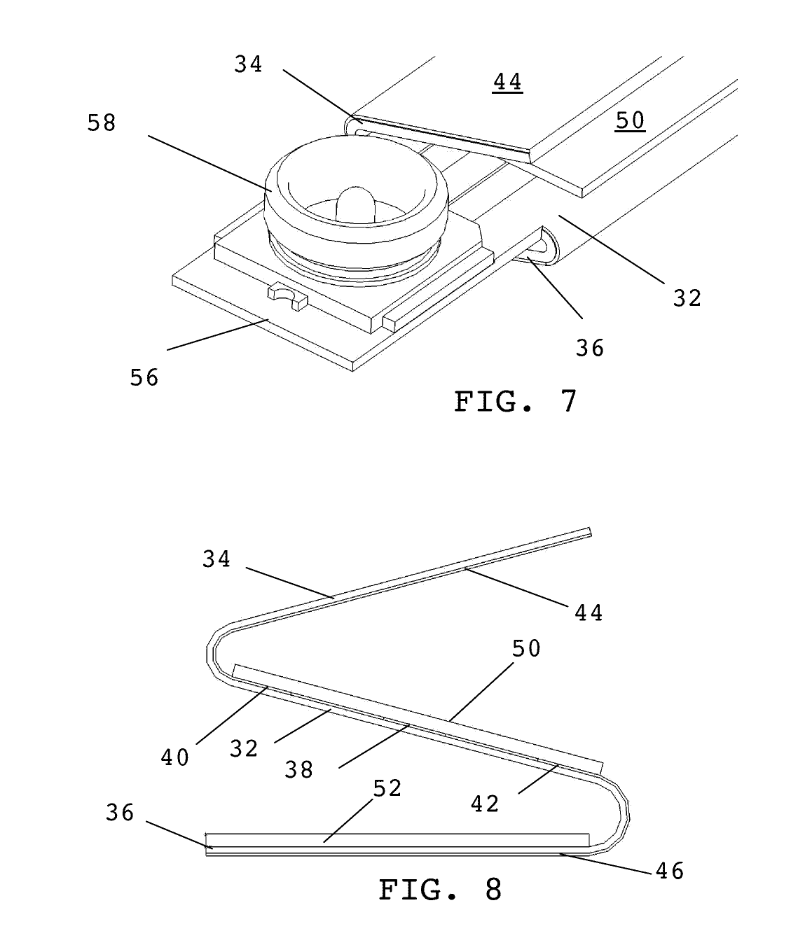

It is possible to have all the conductive material provided on one and the same side of the carrier as is shown in FIG. 8. This figure shows the same elements as in FIG. 3. The difference here is that the first solid area 44 of conductive material on the first lateral section 34 is provided on the first side of the carrier. It is in this case also joined with the first secondary conductive trace 40. They, thus form one unit stretching from the first end to the second end. The use of a single-sided flexfilm carrying conductive material on only one side of the flexfilm improves the economy of the production of the device even further.

It can furthermore be mentioned that whether a double-sided or a single-sided flexfilm is used, i.e., a flexfilm having conductive material on two sides or one side, can furthermore be decided by the second part of the carrier and more particularly on if this second part of the carrier uses one or two sides. Two sides may for instance be used for carrying more than one antenna pattern.

A further variation is also possible to include further traces on the first part of the connector, for instance DC signal traces. Such traces may be of interest if the element connected to the second end of the first part of the carrier is a speaker.

In this case, at least one lateral section is wider than the midsection and the side which is provided with a solid area of conductive material also includes a tertiary conductive trace stretching in the first direction from the first end to the second end of the first part separated from said solid area. Here, either the first, second or both of the first and second lateral sections may be provided with such a tertiary conductive trace. This tertiary conductive trace may then be provided on a part of the lateral section, which when the first part is folded, stretches out beyond the edge where the midsection is joined to the other lateral section.

Various variations of a signal transmission device invention have been described above. The person skilled in the art realizes that these can be varied within the scope of the appended claims without departing from the inventive idea. Exemplary embodiments are also directed towards portable radio communication devices including such signal transmission devices.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms (e.g., different materials, etc.), and that neither should be construed to limit the scope of the disclosure. In some example embodiments, well-known processes, well-known device structures, and well-known technologies are not described in detail. In addition, advantages and improvements that may be achieved with one or more exemplary embodiments of the present disclosure are provided for purpose of illustration only and do not limit the scope of the present disclosure, as exemplary embodiments disclosed herein may provide all or none of the above mentioned advantages and improvements and still fall within the scope of the present disclosure.

Specific dimensions, specific materials, and/or specific shapes disclosed herein are example in nature and do not limit the scope of the present disclosure. The disclosure herein of particular values and particular ranges of values (e.g., frequency ranges or bandwidths, etc.) for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter (i.e., the disclosure of a first value and a second value for a given parameter can be interpreted as disclosing that any value between the first and second values could also be employed for the given parameter). Similarly, it is envisioned that disclosure of two or more ranges of values for a parameter (whether such ranges are nested, overlapping or distinct) subsume all possible combination of ranges for the value that might be claimed using endpoints of the disclosed ranges.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items. The term “about” when applied to values indicates that the calculation or the measurement allows some slight imprecision in the value (with some approach to exactness in the value; approximately or reasonably close to the value; nearly). If, for some reason, the imprecision provided by “about” is not otherwise understood in the art with this ordinary meaning, then “about” as used herein indicates at least variations that may arise from ordinary methods of measuring or using such parameters. For example, the terms “generally”, “about”, and “substantially” may be used herein to mean within manufacturing tolerances.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements, intended or stated uses, or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed:

1. A signal transmission device comprising a foldable conductive trace carrier having a first side, a second side, and a first part having a first lateral section, a second lateral section, and a midsection between the first and second lateral sections, wherein:
the midsection includes a first central primary conductive trace on the first side of the carrier and first and second secondary conductive traces respectively on each side of the primary conductive trace on the first side of the carrier;
the first part of the carrier is foldable for folding the first lateral section over the first side of the midsection and the second lateral section under the second, opposite side of the midsection to thereby cover the midsection; and
the first lateral section includes a first solid area of conductive material and the second lateral section includes a second solid area of conductive material for forming a shielded conductor when the first part of the carrier is folded.

2. The signal transmission device of claim 1, wherein:
the first part has a first end and a second end; and
the first central primary conductive trace stretches in a first direction on the first side of the carrier from the first end of the first part to the second end of the first part.

3. The signal transmission device of claim 2, wherein the first solid area of conductive material of the first lateral section stretches along the first direction for the whole length of the first part of the carrier.

4. The signal transmission device of claim 1, further comprising a connecting part joined to the first end of the first part of the carrier, where the central primary conductive trace and the secondary conductive traces stretch out onto the connecting part for allowing a connector to be mounted onto the connecting part in electrical contact with at least the primary conductive trace.

5. The signal transmission device of claim 1, wherein the first and second secondary conductive traces are placed in parallel with and at the same distance from the primary conductive trace.

6. The signal transmission device of claim 1, wherein the second solid area of conductive material of the second lateral section is on the first side of the carrier and joined with the second secondary conductive trace of the midsection.

7. The signal transmission device of claim 6, wherein the second solid area of conductive material of the second lateral section that is joined with the second secondary conductive trace of the midsection stretches, when the first part of the carrier is folded, in parallel with the midsection from a first position where it is joined to the second secondary conductive trace to a second position where this second solid area at least partly covers the first secondary conductive trace.

8. The signal transmission device of claim 1, wherein the first solid area of conductive material of the first lateral section stretches, when the first part of the carrier is folded, in parallel with the midsection from a first position covering the first secondary conductive trace to a second position at least partly covering the second secondary conductive trace.

9. The signal transmission device of claim 1, wherein the first solid area of conductive material of the first lateral section is on the second side of the carrier.

10. The signal transmission device of claim 9, wherein the midsection includes a third solid area of conductive material on the second side of the carrier and aligned with the first secondary conductive trace.

11. The signal transmission device of claim 1, wherein the first secondary conductive trace is electrically connected to conductive material of the first lateral section.

12. The signal transmission device of claim 11, wherein the electrical connection is provided through at least one via going through the midsection of the carrier.

13. The signal transmission device of claim 1, wherein the first solid area of conductive material of the first lateral section is on the first side of the carrier and joined with the first secondary conductive trace of the midsection.

14. The signal transmission device of claim 1, wherein:
at least one lateral section is wider than the midsection; and
the side of the second lateral section which includes a solid area of conductive material also includes a tertiary conductive trace separated from the solid area.

15. The signal transmission device of claim 1, wherein the carrier comprises a second part with an element connected at least to the central conductive trace.

16. The signal transmission device of claim 1, wherein:
at least the first part of the carrier is folded; and
the signal transmission device further comprises:
a first layer of adhesive material between the first lateral section and the midsection of the first part of the carrier; and
a second layer of adhesive material between the second lateral section and the midsection of the first part of the carrier.

17. The signal transmission device of claim 16, wherein the second layer of adhesive material is thicker than the first layer of adhesive material for providing the same distance between conductive material on the second side of the first lateral section and conductive material on the midsection as between conductive material on the first side of the second lateral section and the midsection.

18. A portable radio communication device comprising the signal transmission device of claim 1.
